(19) United States
(12) Patent Application Publication
(10) Pub. No.: US 2013/0089954 A1
(43) Pub. Date: Apr. 11, 2013

(54) METHOD OF FABRICATING ELECTRONIC DEVICE HAVING FLEXIBLE DEVICE

(71) Applicant: EnSilTech Corporation, Seoul (KR)

(72) Inventors: Jae-Sang RO, Seoul (KR); Won-Eui HONG, Seoul (KR); Seog-Young LEE, Seoul (KR); Ingoo JANG, Seoul (KR)

(73) Assignee: EnSilTech Corporation, Seoul (KR)

(21) Appl. No.: 13/646,660

(22) Filed: Oct. 6, 2012

(30) Foreign Application Priority Data
Oct. 6, 2011 (KR) 10-2011-101582

(51) Int. Cl. H01L 21/78

(52) U.S. Cl. 438/113; 257/E21.599

(57) ABSTRACT

There is provided a method of fabricating an electronic device having a flexible device, which is fabricated using a support substrate by Joule-heating induced film separation (JIFS). A method of fabricating an electronic device having a flexible device includes providing a support substrate, coating a conductive layer on one surface of the support substrate, forming a plastic substrate on the other surface of the support substrate, forming one or more thin-film transistors (TFTs) on the plastic substrate, forming an electronic device electrically connected to any one of the TFTs, and separating the plastic substrate from the conductive layer by generating Joule-heating through application of an electric field to the conductive layer. Accordingly, the flexible device can be separated from the support substrate without deformation of the support substrate and degradation of the electronic device. Since the separation time is short, it is easy to fabricate a large-area device, and the fabrication yield can be improved.

### BACKGROUND OF THE INVENTION

1. Field of the Invention

The present invention relates to a method of fabricating an electronic device having a flexible device. More particularly, the present invention relates to a method of fabricating an electronic device having a flexible device, which is fabricated using a support substrate by Joule-heating induced film separation (JIFS).

2. Description of the Related Art

In general, displays are divided into a liquid crystal display (LCD), a field emission display (FED), an organic light emitting display (OLED), etc.

Such a display is formed on a transparent glass substrate through which light can be transmitted, but the glass substrate cannot implement a flexible display.

Thus, a flexible display can be implemented using a flexible glass substrate thinner than the conventional glass substrate, a plastic substrate that has an excellent flexible characteristic and is not easily damaged by an external impact, and a metal substrate that has excellent thermal resistance and is flexible.

However, since the flexible substrate is flexible and very thin, there is a problem in dealing with the flexible substrate in a fabrication process of a flat panel display, including a cleansing process, a thin-film deposition process, a patterning process, etc.

As a result, the fabricating process can be easily performed by bonding a support substrate relatively thicker than the flexible substrate on one surface of the flexible substrate.

As such, a flat panel display such as an OLED is formed on the flexible substrate bonded to the support substrate, and a process of removing the support substrate by detaching the support substrate from the flexible substrate is then performed in order to secure the flexibility that is an original characteristic of the flexible substrate.

A typical detaching process is a laser lift-off process using laser. The process time of the laser used in the laser lift-off process is long, and the maintenance and management cost of the laser is large. Hence, a new detaching process is required.

A process called as SUFTAL (Seiko-Epson Co. Ltd.) is used as another method of fabricating an electronic device having the flexible substrate described above. The SUFTAL is a process of fabricating an electronic device having a flexible substrate through double transfer.

In the process, a SiO₂ layer and an amorphous silicon layer are formed on a glass substrate, and a low-temperature multi-crystalline thin film transistor (TFT) array is fabricated on the glass substrate having the SiO₂ layer and the amorphous silicon layer. Subsequently, a water-soluble adhesive is formed on the top of the TFT array so that the TFT array is attached to a first plastic substrate, and the TFT array is then separated from the lower glass substrate by irradiating XeCl laser onto the bottom surface of the amorphous silicon layer through the lower glass substrate. Thereafter, a second plastic layer is laminated on the bottom surface of the TFT array using a permanent adhesive, and the TFT array is then separated from the first plastic substrate by dissolving the water-soluble adhesive.

In this case, since no less than 2% hydrogen is contained in the amorphous silicon layer, the glass substrate and the TFT array is physically exfoliated by the generation of H₂ gas when the laser is absorbed into the amorphous silicon.

However, the exfoliation is incomplete using only the generated H₂ gas in the process. Since two transfer processes are used in the process, high cost incurred, and it is expected that a yield problem will occur. Since the TFT array has general geometric characteristics, there may occur a problem when a flat display is obtained by laminating (attaching) the TFT array on the plastic substrate. In the fabrication of cells, there occurs a problem in mass production due to difficulty in substrate handling and alignment.

Another transfer process includes forming a low-temperature poly-silicon TFT array on a SiO₂ layer on a glass substrate, and an arbitrary plastic substrate is attached on the TFT array using a water-soluble adhesive. However, the process is different from the process described above in that the glass substrate is removed through etching using HF. Then, the TFT array is transferred on a permanent plastic substrate, and the arbitrary plastic substrate is removed by dissolving the water-soluble adhesive. However, since the entire glass substrate is completely removed through the etching, the process requires high cost and is not environmentally friendly.

In addition, there are other processes of removing the flexible device and the glass substrate using laser.

For example, in PCT Publication No. WO 2005/50754, a plastic substrate is formed to overlap with a solid carrier substrate (active and passive substrates), and pixel circuits are formed over the plastic substrate. Subsequently, if cells are formed on the plastic substrate, the carrier substrate (active and passive plate substrates) is removed from the plastic substrate using laser. In this case, an amorphous silicon layer containing no less than 7% hydrogen is formed as a separation layer between the carrier substrate and the plastic substrate so that the carrier substrate is well removed from the plastic substrate.

However, in the method described above, although beam focusing is performed on the glass substrate and the plastic substrate, the energy distribution of the laser has a Gaussian distribution. Hence, melting caused by heat generated in an organic matter and ablation of a carbon chain in the organic matter occur at the same time, depending on the level of energy applied. Therefore, the heat generation of the organic matter, accompanied by the melting, causes heat damage to an organic layer of an upper circuit array, thereby resulting in deformation of the organic layer and influence on the upper circuit array.

Further, in a case where an amorphous silicon layer containing hydrogen is used as the separation layer, the same problem as that in the process called as the SUFTAL described above occurs.

In addition, there has been proposed a method for facilitating separation using an intermediate layer having a high laser absorption rate, but the structure of a material constituting the intermediate layer is not optimized.

### SUMMARY OF THE INVENTION

The present invention is conceived to solve the aforementioned problems. Accordingly, an object of the present invention is to provide a method of fabricating an electronic device having a flexible device, in which the flexible device is easily separated from a support substrate without deformation of a plastic substrate or degradation of the flexible device.

According to an aspect of the present invention, there is provided a method of fabricating an electronic device having a flexible device, the method including: providing a support substrate; coating a conductive layer on one surface of the support substrate; forming a plastic substrate on the other surface of the support substrate; forming one or more thin-film transistors (TFTs) on the plastic substrate; forming an electronic device electrically connected to any one of the TFTs; and separating the plastic substrate from the conductive layer by generating Joule-heating through application of an electric field to the conductive layer.

According to another aspect of the present invention, there is provided a method of fabricating an electronic device having a flexible device, the method including: providing a support substrate; forming a plastic substrate on one surface of the support substrate; forming one or more TFTs on the plastic substrate; forming an electronic device electrically connected to any one of the TFTs; forming a conductive layer on the other surface of the support substrate, on which the electronic device is completed; and separating the plastic substrate from the conductive layer by generating Joule-heating through application of an electric field to the conductive layer.

According to still another aspect of the present invention, there is provided a method of fabricating an electronic device having a flexible device, the method including: providing a support substrate; forming a plastic substrate on one surface of the support substrate; forming one or more TFTs on the plastic substrate; forming an electronic device electrically connected to any one of the TFTs; separately providing a conductive-layer forming substrate; forming a conductive layer on the conductive-layer forming substrate; contacting the conductive layer formed on the conductive-layer forming substrate with the support substrate; and separating the plastic substrate from the conductive layer by generating Joule-heating through application of an electric field to the conductive layer.

The conductive layer may be made of a transparent or opaque conductive material. The transparent conductive material may be a transparent conductive oxide layer made of ITO, IZO, AZO, IGZO, In₂O₃ or ZnO. The opaque conductive material may include a metal such as Mo, Cr, W, Ti, Cu, Al, Ni or MoW, or metal alloy. However, the present invention is not limited thereto, the conductive layer include all materials having conductivity.

The support substrate may be a glass or quartz substrate.

The plastic substrate may be made of acryl, polyethylene, polypropylene, polyimide, parylene, polyethylene naphthalene (PEN), polyether sulfone (PES), polyethylene terephthalate (PET), polycarbonate, polyester, polyurethane, polystyrene, polyacetyl or mylar.

An electrode contacts an upper surface of the conductive layer.

The electronic device may be an organic light emitting display (OLED), liquid crystal display (LCD), solar cell, E-ink paper, plasma display panel (PDP), surface-conduction electron-emitter display (SED) or field emission display (FED).

The method may further include forming a sacrificial layer before or after forming the conductive layer.

The sacrificial layer may be made of a material having a lower glass transition temperature Tg than the plastic substrate. The sacrificial layer may include polyvinylbutyral (PVB), polyethylene (PE), acryl resin, carbon nano-tube (CNT) or epoxy resin.

### BRIEF DESCRIPTION OF THE DRAWINGS

Exemplary embodiments of the present invention can be understood in more detail from the following description taken in conjunction with the accompanying drawings, in which:

FIGS. 1A to 1F are sectional views illustrating a method of fabricating an electronic device having a flexible device according to a first embodiment of the present invention;

FIGS. 2A and 2B are sectional views illustrating a method of fabricating an electronic device having a flexible device according to a second embodiment of the present invention;

FIGS. 3A to 3C are sectional views illustrating a method of fabricating an electronic device having a flexible device according to a third embodiment of the present invention;

FIGS. 4A and 4B are sectional views illustrating a method of fabricating an electronic device having a flexible device according to a fourth embodiment of the present invention; and

FIG. 5 illustrates an embodiment in which a flexible display fabricated according to the present invention is separated from a support substrate so as to be applied to a mobile device.

### DETAILED DESCRIPTION OF THE INVENTION

Hereinafter, exemplary embodiments of the present invention will be described in detail with reference to the accompanying drawings. The following embodiments are provided only for illustrative purposes so that those skilled in the art can fully understand the spirit of the present invention. Therefore, the present invention is not limited to the following embodiments but may be implemented in other forms. In the drawings, the widths, lengths, thicknesses and the like of elements are exaggerated for convenience of illustration. Like reference numerals indicate like elements throughout the specification and drawings.

In the present invention, Joule heating is generated by applying an electric field to a metal layer or metal alloy layer. The Joule heating refers to heating using heat generated by a resistor when current flows through a conductor.

The amount of energy per unit time, which is applied to a conductive layer, i.e., a metal layer in the present invention by Joule heating generated by applying an electric field to the conductive layer, is as follows.

W=V×I

In the formula, W denotes an amount of energy per unit time in the Joule heating, V denotes a voltage applied to both ends of the conductive layer, and I denotes current.

From the formula, it can be seen that the amount of energy per unit time, applied to the conductive layer, is increased by the Joule heating as the voltage V increases and/or as the current I increases. If the temperature of the conductive layer is increased by the Joule heating, heat is conducted to a plastic substrate (plastic substrate for a flexible device) positioned on an upper or lower surface of the conductive layer and a support substrate (e.g., a glass substrate) positioned beneath the plastic substrate.

Therefore, in the present invention, appropriate voltage and current is applied to a sample for a short period of time in order to increase the temperature of the conductive layer, at which the plastic substrate and the glass substrate can be separated by the thermal conduction without thermal deformation of the plastic substrate or the glass substrate. Since the electric field applied to the sample is determined by various factors such as resistance, length and thickness of the conductive layer, it is difficult to specify the electric field. However, the application of the electric field is performed in consideration of ordinary process conditions, and for example, an electric field of about 1 to 1,000 kw/cm² is applied to the sample. The one-time application time of the electric field may be 1/1,000,000 to 100 seconds, preferably 1/1,000,000 to 1 second. If the amount of energy applied is satisfactory, the separation process between the glass substrate and the plastic substrate may be finished with only a one-time shot. If the amount of energy applied is unsatisfactory, the separation process between the glass substrate and a plastic film may be performed with several-time shots. The process of separating the plastic film from the glass substrate using the Joule heating is referred to as Joule-heating induced film separation (JIFS).

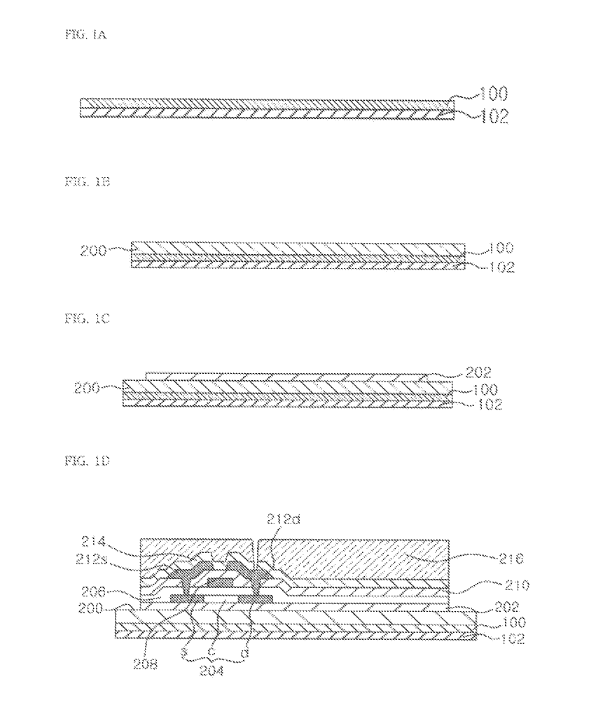

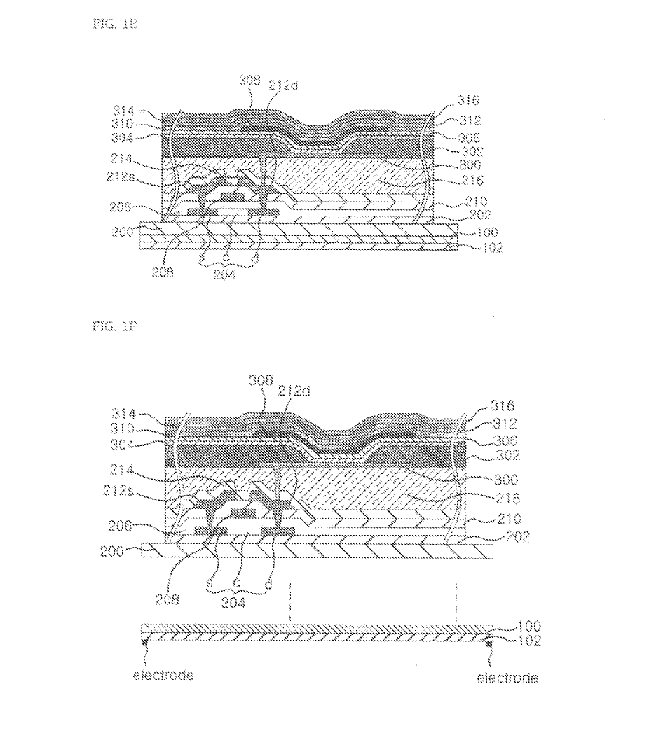

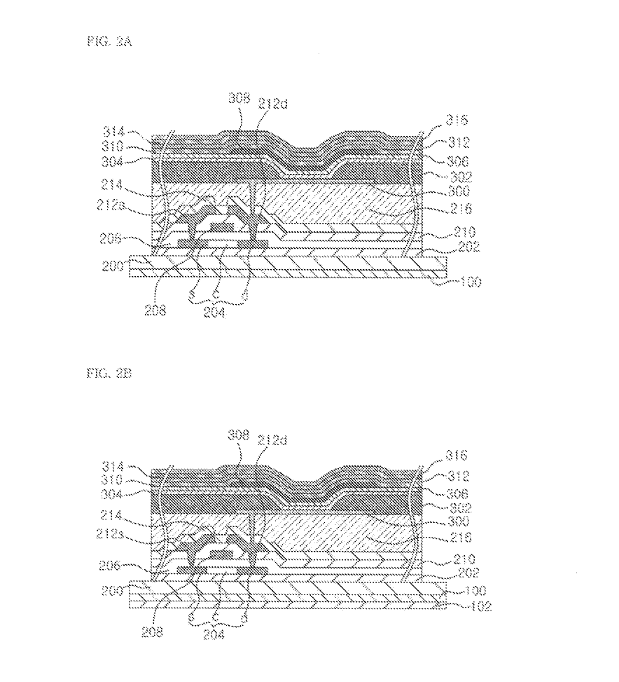

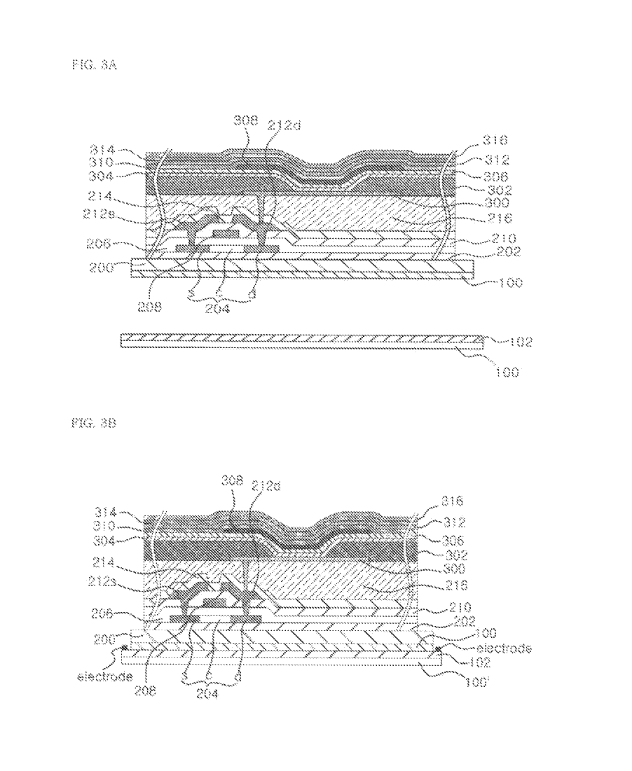

FIGS. 1A to 1F are sectional views illustrating a method of fabricating an electronic device having a flexible device according to a first embodiment of the present invention.

Referring to FIG. 1A, a conductive layer 102 is formed as a heating layer on one surface of a support substrate 100. A solid substrate having a sufficient mechanical strength and no deformation when various devices or layers are formed thereon may be used as the support substrate 100. For example, the support substrate 100 may include a glass substrate, a quartz substrate, etc.

The conductive layer 102 is made of a transparent or opaque conductive material, and may include transparent conductive oxide, metal and metal alloy, preferably ITO, IZO, ZnO, Mo, Cr, W, Ti, MoW, etc. The conductive layer 102 is deposited using a sputtering method or phase deposition method, and all methods capable of depositing the conductive layer known in the art may be applied as other methods.

It is necessary to maintain the thickness of the conductive layer 102 to be uniform so that the conductive layer 102 is uniformly heated using the Joule heating caused by the application of an electric field in a subsequent process. The conductive layer 102 may be formed to have a thickness of 500 to 10,000 Å, but the present invention is not limited thereto.

Referring to FIG. 1B, a plastic substrate 200 is formed on a surface opposite to the surface of the support substrate 100, on which the conductive layer is formed.

The plastic substrate 200 acts as a flexible substrate in a final flexible device, and has a characteristic that is not broken well and makes it possible to implement a curved surface. A flexible device is formed over the plastic substrate 200.

As the thickness of the plastic substrate 200 is thinner, the implementation of the curved surface is easier. However, the thickness of the plastic substrate 200 is necessarily ensured so that after the support substrate 100 is separated from the plastic substrate 200 in a separation process of the support substrate 100, which will be described later, layers and devices formed on the plastic substrate 200 can be maintained by the plastic substrate 200. Therefore, the thickness of the plastic substrate 200 is preferably 10 to 100 μm.

For example, an organic layer for high temperature, of which properties are not changed at a high temperature, may be used as the plastic substrate 200. The plastic substrate 200 may be made of acryl, polyethylene, polypropylene, polyimide, parylene, polyethylene naphthalene (PEN), polyether sulfone (PES), polyethylene terephthalate (PET), polycarbonate, polyester, polyurethane, polystyrene, polyacetyl, mylar, or another plastic material. However, the present invention is not limited thereto, and a plastic substrate known in the art may be used as long as it is suitable for the use of the plastic substrate 200.

Among these materials, the polyimide has excellent mechanical property and thermal resistance. Thus, in a case where a device is formed on a plastic film in a subsequent process, the plastic film has thermal stability even in a high-temperature process. Further, the plastic film is not deformed even in a Joule-heating induced film separation (JIFS) process applied when the support substrate and the plastic layer are separated after the flexible device is sealed.

The plastic substrate 200 is formed on the support substrate 100 using an ordinary coating method such as a spin coating method.

Referring to FIG. 1C, a passivation layer 202 is formed on the plastic substrate 200 so as to prevent moisture from penetrating the plastic substrate 200 and to ensure thermal resistance. Thus, a standard process can be applied without a separate preprocessing process in a subsequent process of fabricating the flexible device.

The passivation layer 202 uses only an inorganic material layer, but may use a composite layer of an inorganic material layer, and a polymer layer.

The inorganic material layer may include metal oxide, metal nitride, metal carbide, metal oxynitride and compound thereof. The metal oxide may include SiO2, alumina, titania, indium oxide, tin oxide, indium tin oxide, and compound thereof. The metal nitride may include aluminum nitride, silicon nitride, and compound thereof. The metal carbide may include silicon carbide, and metal oxynitride may include silicon oxynitride. In addition, the inorganic material layer may include any inorganic material such as silicon, which can prevent moisture and oxygen from penetrating the plastic substrate 200.

Meanwhile, the inorganic material layer may be formed through deposition. In a case where the inorganic material layer is formed as described above, there is a limitation that a void provided in the inorganic material layer is grown as it is. Therefore, to prevent the void from being continuously grown at the same position, a polymer layer may be further provided separately from the inorganic material layer.

The polymer layer may include an organic polymer, an inorganic polymer, organometallic polymer, a hybrid organic/inorganic polymer, etc.

The passivation layer 202 is formed using a deposition method such as a plasma-enhanced chemical vapor deposition (PECVD) technique, which is known in the art.

Referring to FIG. 1D, after the passivation layer 202 is formed, an electronic device including a thin film transistor (hereinafter, referred to as TFT) is formed on the passivation layer 202.

The TFT may include a poly-silicon TFT, an a-silicon TFT, an organic TFT, etc.

In a case where the organic TFT is used, various organic semiconductor materials such as pentacene may be used for the organic TFT.

In a case where the poly-silicon TFT is used, a poly-silicon semiconductor layer formed by performing a crystallization process on an amorphous silicon layer is used as a semiconductor layer. The crystallization process may be performed using a rapid thermal annealing (RTA) method, a solid phase crystallization (SPC) method, an excimer laser annealing (ELA) method, a metal induced crystallization (MIC) method, a metal induced lateral crystallization (MILC) method, a super grained silicone (SGS) method, a sequential lateral solidification (SLS) method, a Joule heating crystallization (JIC) method, etc. Since a lower substrate is formed with the plastic substrate, its process temperature is limited. Therefore, the poly-silicon TFT is preferably formed using a low temperature polysilicone (LTPS) method.

To fabricate the poly-silicon TFT, an amorphous silicon is first coated on the passivation layer 202. Subsequently, the amorphous silicon is crystallized using one of the crystallization methods described above. An island-shaped semiconductor layer pattern 204 is formed by patterning the amorphous silicon before the crystallization or patterning the poly-silicon before the crystallization.

A gate insulating layer 206 is coated on the semiconductor layer pattern 204 over an entire surface of the substrate. The gate insulating layer 206 may include silicon oxide, silicon nitride, or composite thereof.

Subsequently, a gate electrode 208 is formed by coating a gate electrode material on the gate insulating layer 206 and then patterning the gate insulating layer 206 having the gate electrode material coated thereon. The gate electrode material includes an ordinary gate electrode material. For example, the gate electrode material may include a material such as Mg, Al, Ni, Cr, Mo, W, MoW or Au, and may be formed in a single or a plurality of layers thereof.

After the gate electrode 208 is formed, an interlayer insulating layer 210 is formed.

The interlayer insulating layer 210 may be formed of an insulative material such as silicon oxide or silicon nitride. In addition, the interlayer insulating layer 210 may be formed of an insulative organic material. After the interlayer insulating layer 210 is formed, contact holes having source/drain regions s and d exposed therethrough are formed by patterning portions corresponding to the source/drain regions s and d of the semiconductor layer 204 in the interlayer insulating layer 210, respectively.

Then, source and drain electrodes 212s and 212d are formed by respectively coating source/drain electrode materials over the source/drain regions s and d and patterning the coated source/drain electrode materials.

The TFT is completed through the process described above.

Although a top-gate type TFT has been described as the TFT in this embodiment, a bottom-gate type TFT in which the gate electrode is positioned below the semiconductor layer may be applied to the TFT. Although the standard process is applied in this embodiment, a change in process order or change in process condition may be made based on any technique known by those skilled in the art.

Various electronic devices may be formed above the TFT. Hereinafter, an OLED will be described for convenience of illustration.

After the source/drain electrodes 212s and 212d are formed, a passivation layer 214 and/or a planarization layer 216 are/is formed on the source/drain electrodes 212s and 212d.

The passivation layer 214 and the planarization layer 216 may be formed of an organic material such as benzocyclobutene (BCB) or acryl, an inorganic material such as SiNx or silicon oxide, etc. The passivation layer 214 and the planarization layer 216 may be formed in a single layer or multiple layers, and various modifications are possible according to process conditions.

A via-hole is formed by patterning the passivation layer 214 and/or the planarization layer 216 through a photolithography process.

Referring to FIG. 1E, a first electrode 300 electrically connected to the source or drain electrode 212s or 212d of the TFT is formed on the passivation layer 214 or the planarization layer 216.

The first electrode 300 is used as one of electrodes provided in a display device, and may include a reflective electrode or transparent electrode.

The transparent electrode may be used by forming a transparent conductive oxide using ITO, IZO, ZnO or In₂O₃ or by forming a metal thin film using Ag, Mg, Ca, Al, Pt, Pd, Au, Ni, Nd, Ir, Cr or compound thereof, so that light can be transmitted through the transparent electrode.

The reflective electrode may be used by forming a metal layer to a predetermined thickness or more using Ag, Ma, Ca, Al, Pt, Pd, Au, Ni, Nd, Ir, Cr or compound thereof. Alternatively, the reflective electrode may be formed in a multi-structure in which a transparent conductive oxide layer, i.e., ITO, IZO, ZnO or In₂O₃, is formed on the metal layer as a reflective layer.

The first electrode 300 may be an anode electrode or cathode electrode.

The first electrode 300 may be formed using an ordinary film forming method such as a sputtering method or vapor deposition method, but the present invention is not limited thereto.

Subsequently, a pixel-defining layer 302 patterned using an insulative material is formed on the first electrode 300 so as to expose a portion of the first electrode 300 therethrough. The pixel-defining layer 302 may be made of an organic insulating material such as acryl resin or polyimide resin, or an inorganic insulating material.

After the pixel-defining layer 302 is formed, first intermediate layers 304 and 306 are formed over the entire surface of the substrate. A hole injection layer and/or a hole transport layer, or an electron injection layer and/or an electron transport layer are/is formed as the first intermediate layers 304 and 306. The hole injection layer and/or the hole transport layer, and the electron injection layer and/or the electron transport layer are/is formed through the standard process, and may be modified by those skilled in the art according to the process conditions.

The hole injection layer may be formed using cupper phthalocyanine (CuPc), TANTA, TCTA, TDAPB, TDATA, polyaniline (PANI), poly(3,4)-ethylenedioxythiophene (PEDOT), etc. The hole transport layer may be formed using N,N′-dinaphthyl-N,N′-diphenyl benxidine (NPD), N,N′-Bis-(3-methylphenyl)-N,N′-bis-(phenyl)-benzidine (TPD), 4,4′,4″-Tris(N-3-methylphenyl-N-phenyl-amino)-triphenylamine (s-TAD,MTDATA), PVK, etc.

The electron transport layer may be formed using a high molecular material such as PBD, TAZ or spiro-PBD, or a low molecular material such as tris(8-quinolinolato)aluminum (Alq3), BAlq or SAlq. The electron injection layer may be formed using Alq3, lithium fluoride (LiF), Ga complex or PBD.

Subsequently, a light emitting layer 308 is formed. The light emitting layer 308 is formed for each of R, G and B, and may be formed of a phosphorescent or fluorescent material. For example, all the R, G and B light emitting layers may be formed using the phosphorescent or fluorescent material or using a combination of the phosphorescent or fluorescent material.

In a case where the light emitting layer 308 is a fluorescent light emitting layer, the fluorescent light emitting layer may include Alq3, distyrylarylene (DSA), DSA derivatives, distyrylbenzene (DSB), DSB derivatives; 4,4′-bis(2,2′-diphenyl vinyl)-1,1′-biphenyl (DPVBi), DPVBi derivatives, spiro-DPVBi, spirosexyphenyl (spiro-6P), etc., but the present invention is not limited thereto. In a case where the light emitting layer 308 is a phosphorescent light emitting layer, the phosphorescent light emitting layer may include a host material such as an arylamine-based material, carbazole-based material or spiro-based material, preferably 4,4-N,N dicarbazole-biphenyl (CBP), CBP derivatives, N,N-dicarbazolyl-3,5-benzene (mCP), mCP derivatives or spiro-series derivatives. The phosphorescent light emitting layer may include a dopant material such as a phosphorescent organic metal complex having a central metal such as Ir, Pt, Tb or Eu. The phosphorescent organic metal complex may include PQIr, PQIr(acac), PQ2Ir(acac), PIQIr(acac), PtOEP, etc., but the present invention is not limited thereto.

The light emitting layer 308 may be formed by a vacuum deposition method using a fine metal mask, an ink jet printing method, a laser induced thermal imaging method, etc., but the present invention is not limited thereto.

Second intermediate layers 310 and 312 are formed on the light emitting layer 308 over the entire surface of the substrate. A hole injection layer and/or a hole transport layer, or an electron injection layer and/or an electron transport layer are/is formed as the second intermediate layers 310 and 312. In a case where the hole injection layer and/or the hole transport layer are/is formed as the first intermediate layers 304 and 306 on the first electrode 300 as described above, the electron injection layer and/or the electron transport layer are/is formed as the second intermediate layers 310 and 312. In a case where the electron injection layer and/or the electron transport layer are/is formed as the first intermediate layers 304 and 306, the hole injection layer and/or the hole transport layer are/is formed as the second intermediate layers 310 and 312. In addition, a hole blocking layer (HBL) or electron blocking layer (EBL) may be further formed. The second intermediate layer may be formed using a material used in the first intermediate layer.

The first intermediate layers 304 and 306 and the second intermediate layers 310 and 312 are formed through the standard process, and may be modified by those skilled in the art according to the process conditions.

Subsequently, a second electrode 314 is formed on the second intermediate layers 310 and 312. Like the first electrode, the second electrode 314 may be formed as a reflective electrode or transparent electrode.

The transparent electrode may be used by forming a transparent conductive oxide using ITO, IZO, ZnO or In₂O₃ or by forming a metal thin film using Ag, Mg, Ca, Al, Pt, Pd, Au, Ni, Nd, Ir, Cr or compound thereof, so that light can be transmitted through the transparent electrode.

The reflective electrode may be used by forming a metal layer to a predetermined thickness or more using Ag, Ma, Ca, Al, Pt, Pd, Au, Ni, Nd, Ir, Cr or compound thereof. Alternatively, the reflective electrode may be formed in a multi-structure in which a transparent conductive oxide layer, i.e., ITO, IZO, ZnO or In₂O₃, is formed on the metal layer as a reflective layer.

In a case where the first electrode 300 is an anode electrode, the second electrode 314 becomes a cathode electrode. In a case where the first electrode 300 is a cathode electrode, the second electrode 314 becomes an anode electrode.

After the second electrode 314 is formed, a passivation layer is formed on the second electrode 314 using an inorganic layer, an organic layer or a mixed layer thereof.

After the passivation layer 316 is formed, the display device is sealed. The sealing method may be performed by sealing the display device using a sealing substrate or by encapsulating the entire display device using an organic layer such as parylene.

Referring to FIG. 1F, after the sealing of the display device is finished, a process of separating the flexible device from the support substrate 100 is performed.

The process of separating the flexible device from the support substrate 100 may be performed using the JIFS.

To apply an electric field to the conductive layer 102 formed on the support substrate 100, an electrode is positioned on the conductive layer 102. Subsequently, an electric field is applied by contacting the conductive layer 102 and the electrode with each other. The application of the electric field is formed, for example, by applying energy with power density, which can generate heat of 1,300° C. or more. Since the application of the electric field is by various factors such as length and thickness of the conductive layer 102, it is difficult to specify the electric field. The applied current may be DC current or AC current. The one-time application time of the electric field may be 1/1,000,000 to 100 seconds, preferably 1/1,000,000 to 10 seconds, and more preferably 1/1,000,000 to 1 second. The application of the electric field may be repeated several times using a regular or irregular unit.

If the plastic substrate 200 that is a substrate of the flexible device is separated from the support substrate 100 as described above, the heating time is very shorter than that in the process performed through the existing laser irradiation or UV lamp irradiation, and thus the process time is reduced.

When Joule-heating is performed through the application of the electric field, single-level energy is applied not to have a continuous distribution, and the time taken to perform the Joule-heating is shorter than that in another separation process. Thus, the heat generated in the separation process is not conducted to the device, and accordingly, the flexible device can be highly reliably separated from the support substrate 100 without deformation of the support substrate 100 or degradation of the electronic device.

Since the support substrate 100 is an insulative substrate, it is possible to prevent an arc from being generated when the Joule-heating is performed.

Although it has been described above that the method is applied to an active-matrix OLED (AM OLED) for convenience of illustration, the method may also applied to an AM LCE, a solar cell, an E-ink paper, a plasma display panel (PDP), a surface-conduction electron-emitter display (SED), a field emission display (FED), etc.

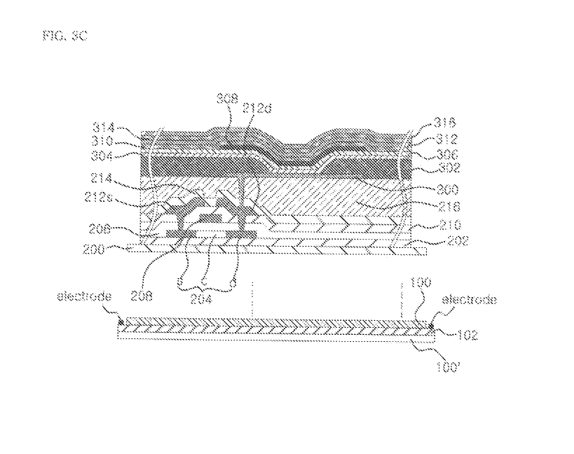

FIGS. 2A and 2B are sectional views illustrating a method of fabricating an electronic device having a flexible device according to a second embodiment of the present invention.

In the first embodiment described above, the conductive layer 102 is first formed on one surface of the support substrate 100, and the flexible device is then formed on the other surface of the support substrate 100. However, in the second embodiment, a flexible device is first formed on one surface of the support substrate 100, and a conductive layer 102 on the other surface of the support substrate 100. Therefore, the second embodiment is different from the first embodiment. A method of fabricating a flexible device in the second embodiment is identical to that in the first embodiment, and therefore, its detailed description will be omitted to avoid redundancy.

Referring to FIG. 2A, the flexible device having the plastic substrate 200 is formed on the support substrate 100 as described in the first embodiment. The forming method of the flexible device is performed identically to that in the first embodiment.

If the flexible device is completed, as shown in FIG. 2B, the conductive layer 102 is formed on the support substrate 100 having a surface opposite to the surface on which the flexible device is formed. The kind and forming method of the conductive layer 102 are identical to those of the first embodiment, and therefore, their detailed descriptions will be omitted.

Then, the plastic substrate 200 is separated from the support substrate 100 by applying an electric field to the conductive layer 102 as described in the first embodiment.

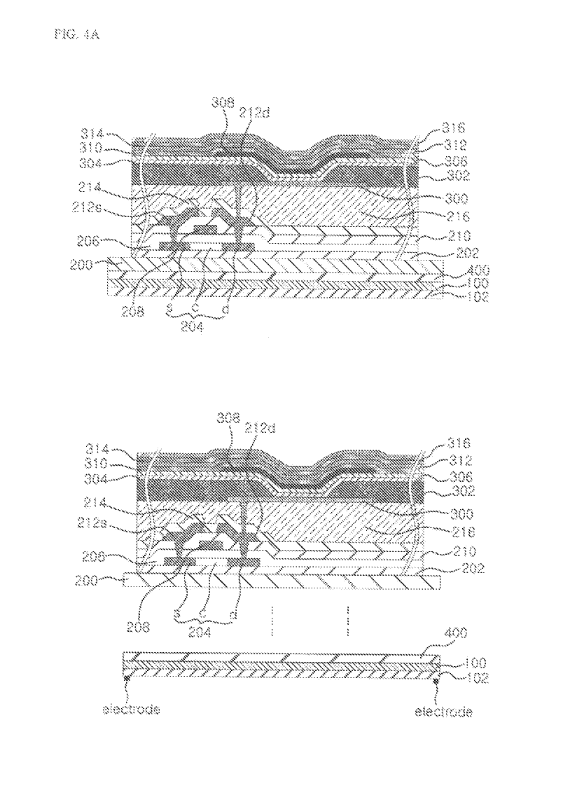

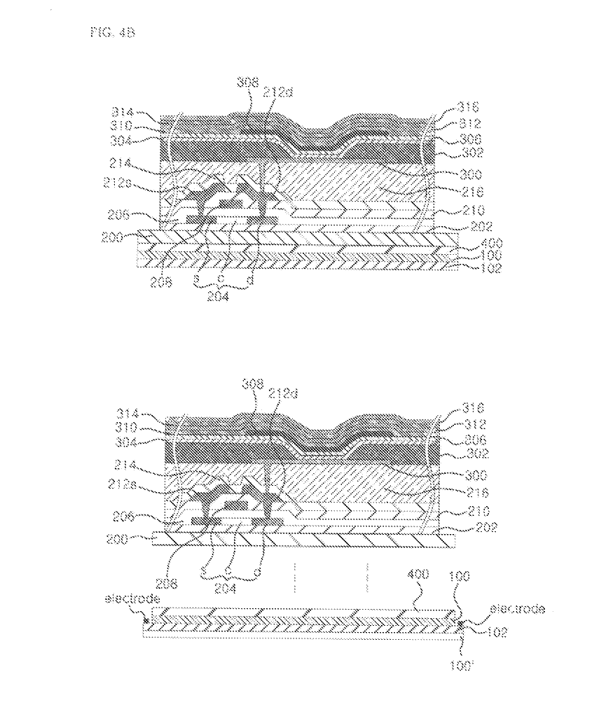

FIGS. 3A to 3C are sectional views illustrating a method of fabricating an electronic device having a flexible device according to a third embodiment of the present invention.

In the first and second embodiments described above, the conductive layer 102 is formed on one surface of the support substrate 100, and the flexible device is formed on the other surface of the support substrate 100. However, in the third embodiment, the plastic substrate 200 of the flexible device is separated from the support substrate 100 by forming the conductive layer 102 on a separate conductive-layer forming substrate 100′, contacting the conductive layer 102 on a surface opposite to the surface of the support substrate 100, on which the flexible device is formed and then applying an electric field to the conductive layer 102.

Specifically, referring to FIG. 3A, the flexible device is formed on one surface of the support substrate. The method of forming the flexible device is identical to that of the first or second embodiment, and therefore, its detailed description will be omitted to avoid redundancy.

Separately from the support substrate 100, the conductive layer 102 is formed on a conductive-layer forming substrate 100′. In this case, the area of the conductive-layer forming substrate 100′ and the conductive layer 102 is necessarily wider than that of the support substrate 100 so that an electric field is applied to the conductive layer 102 in a subsequent process. Meanwhile, the kind and forming method of the conductive layer 102 are identical to those of the first or second embodiment, and therefore, their detailed descriptions will be omitted.

Then, as shown in FIGS. 3B and 3C, the conductive layer 102 formed on the conductive-layer forming substrate 100′ contacts the one surface of the support substrate 100, on which the flexible device is not formed. Subsequently, an electric-field applying electrode contacts the conductive layer 102, and an electric field is applied to the conductive layer 102 through the electric-field applying electrode. Thus, Joule-heating generated in the conductive layer 102 is conducted to the plastic substrate 200 formed on the support substrate 100, so that the plastic substrate 200 is separated from the support substrate 100 by the Joule-heating.

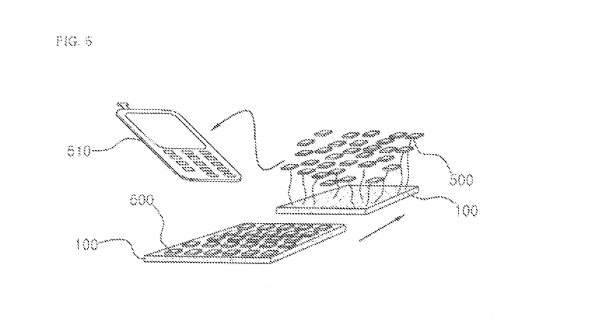

FIGS. 4A and 4B are sectional views illustrating a method of fabricating an electronic device having a flexible device according to a fourth embodiment of the present invention.

In the fourth embodiment, a sacrificial layer 400 is further provided between the support substrate 100 and the plastic substrate 200 in the first to third embodiments described above. Other components are identical to those of the first to third embodiments, and therefore, its detailed description will be omitted to avoid redundancy.

Referring to FIGS. 4A and 4B, heat generated by Joule-heating is conducted to the sacrificial layer 400 formed between the support substrate 100 and the plastic substrate 200, and accordingly, the adhesion between the sacrificial layer 400 and the plastic substrate 200 becomes weak. Thus, the plastic substrate 200 can be easily separated from the support substrate 100.

The sacrificial layer 400 is formed using a low-molecular organic material having a low glass transition temperature Tg, so that a uniform exfoliation of the sacrificial layer 400 with respect to a large-area substrate can be performed even with low energy when the Joule-heating. Since the sacrificial layer 400 is used, the plastic substrate 200 can be easily separated from the support substrate 100, and thermal damage can be more effectively prevent by the heat conducted to the component formed on the plastic substrate 200.

Since the glass transition temperature Tg of the plastic substrate 200 used in the present invention ranges from 350 to 500° C., the glass transition temperature Tg of the sacrificial layer 400 is necessarily lower than that of the plastic substrate 200. The sacrificial layer 400 that satisfies such a condition may include, for example, polyvinylbutyral (PVB), polyethylene (PE), acryl, epoxy, carbon nano-tube (CNT), etc., but the present invention is not limited thereto.

FIG. 5 illustrates an embodiment in which a flexible display 500 fabricated according to the present invention is separated from a support substrate 100 so as to be applied to a mobile device 510. In the present invention, the fabricated flexible device 500 may be applied not only to the mobile device 510 but also to any field to which the flexible device 500 can be applied, such as a flexible solar cell, E-ink paper, PDP, SED or FED.

According to the present invention, when Joule-heating is performed through the application of an electric field, single-level energy is applied not to have a continuous distribution, and the time taken to perform the Joule-heating is shorter than that in another separation process. Thus, the heat generated in a separation process is not conducted to the device, and accordingly, the flexible device can be highly reliably separated from the support substrate without deformation of the support substrate or degradation of the electronic device.

Further, a degree of separation can be controlled according to the shape and thickness of the conductive layer, and the separation time is shorter than that when the separation is performed using laser. Thus, it is easy to fabricate a large-area device, and the fabrication yield can be improved.

Further, since the insulative substrate is formed on the conductive layer in the Joule-heating, it is possible to prevent the occurrence of an arc.

Although some embodiments of the present invention are described for illustrative purposes, it will be apparent to those skilled in the art that various modifications and changes can be made thereto within the scope of the invention without departing from the essential features of the invention. Accordingly, the aforementioned embodiments should to be construed not to limit the technical spirit of the present invention but to be provided for illustrative purposes so that those skilled in the art can fully understand the spirit of the present invention. The scope of the present invention should not be limited to the aforementioned embodiments but defined by appended claims. The technical spirit within the scope substantially identical with the scope of the present invention will be considered to fall in the scope of the present invention defined by the appended claims.

What is claimed is:

1. A method of fabricating an electronic device having a flexible device, the method comprising:
providing a support substrate;
coating a conductive layer on one surface of the support substrate;
forming a plastic substrate on the other surface of the support substrate;
forming one or more thin-film transistors (TFTs) on the plastic substrate;
forming an electronic device electrically connected to any one of the TFTs; and
separating the plastic substrate from the conductive layer by generating Joule-heating through application of an electric field to the conductive layer.

2. The method of claim 1, wherein the plastic substrate is made of acryl, polyethylene, polypropylene, polyimide, parylene, polyethylene naphthalene (PEN), polyether sulfone (PES), polyethylene terephthalate (PET), polycarbonate, polyester, polyurethane, polystyrene, polyacetyl or mylar.

3. The method of claim 1, further comprising forming a sacrificial layer on the support substrate before forming the plastic substrate.

4. The method of claim 3, wherein the sacrificial layer is made of a material having a lower glass transition temperature Tg than the plastic substrate.

5. The method of claim 4, wherein the sacrificial layer includes polyvinylbutyral (PVB), polyethylene (PE), acryl resin, carbon nano-tube (CNT) or epoxy resin.

6. The method of claim 1, wherein the electronic device is an organic light emitting display (OLED), liquid crystal display (LCD), solar cell, E-ink paper, plasma display panel (PDP), surface-conduction electron-emitter display (SED) or field emission display (FED).

7. A method of fabricating an electronic device having a flexible device, the method comprising:
providing a support substrate;
forming a plastic substrate on one surface of the support substrate;
forming one or more TFTs on the plastic substrate;
forming an electronic device electrically connected to any one of the TFTs;
forming a conductive layer on the other surface of the support substrate, on which the electronic device is completed; and
separating the plastic substrate from the conductive layer by generating Joule-heating through application of an electric field to the conductive layer.

8. The method of claim 7, wherein the plastic substrate is made of acryl, polyethylene, polypropylene, polyimide, parylene, PEN, PES, PET, polycarbonate, polyester, polyurethane, polystyrene, polyacetyl or mylar.

9. The method of claim 7, further comprising forming a sacrificial layer on the support substrate before forming the plastic substrate.

10. The method of claim 9, wherein the sacrificial layer is made of a material having a lower glass transition temperature Tg than the plastic substrate.

11. The method of claim 10, wherein the sacrificial layer includes PVB, PE, acryl resin, CNT or epoxy resin.

12. The method of claim 7, wherein the electronic device is an OLED, LCD, solar cell, E-ink paper, PDP, SED or FED.

13. A method of fabricating an electronic device having a flexible device, the method comprising:
providing a support substrate;
forming a plastic substrate on one surface of the support substrate;
forming one or more TFTs on the plastic substrate;
forming an electronic device electrically connected to any one of the TFTs;
separately providing a conductive-layer forming substrate;
forming a conductive layer on the conductive-layer forming substrate;
contacting the conductive layer formed on the conductive-layer forming substrate with the support substrate; and
separating the plastic substrate from the conductive layer by generating Joule-heating through application of an electric field to the conductive layer.

14. The method of claim 13, wherein the conductive layer has a wider area than the support substrate.

15. The method of claim 13, wherein the plastic substrate is made of acryl, polyethylene, polypropylene, polyimide, parylene, PEN, PES, PET, polycarbonate, polyester, polyurethane, polystyrene, polyacetyl or mylar.

16. The method of claim 13, further comprising forming a sacrificial layer on the support substrate before forming the plastic substrate.

17. The method of claim 16, wherein the sacrificial layer is made of a material having a lower glass transition temperature Tg than the plastic substrate.

18. The method of claim 17, wherein the sacrificial layer includes PVB, PE, acryl resin, CNT or epoxy resin.

19. The method of claim 13, wherein the electronic device is an OLED, LCD, solar cell, E-ink paper, PDP, SED or FED.
